(19) United States
(12) Patent Application Publication
(10) Pub. No.: US 2024/0018689 A1
(43) Pub. Date: Jan. 18, 2024

(54) Crystal Puller for Pulling Monocrystalline Silicon Ingots

(71) Applicant: XI’AN ESWIN MATERIAL TECHNOLOGY CO., LTD., Xi'an (CN)

(72) Inventors: Peng Xu, Xi'an (CN); Wanwan Zhang, Xi'an (CN)

(21) Appl. No.: 18/256,377

(22) PCT Filed: Sep. 28, 2022
(86) PCT No.: PCT/CN2022/122175

§ 371 Date: Jun. 7, 2023

(30) Foreign Application Priority Data
Sep. 28, 2021 (CN) 202111146606.2

(51) Int. Cl. C30B 29/06; C30B 15/22; C30B 15/30; C30B 33/02

(52) U.S. Cl. CPC C30B 29/06; C30B 15/22; C30B 15/30; C30B 33/02

(57) ABSTRACT

Embodiments of the present disclosure disclose a crystal puller for pulling a monocrystalline silicon ingot comprising a heater configured with a heat treatment chamber. The heater is arranged in the crystal puller such that the monocrystalline silicon ingot is accessible to the heat treatment chamber by moving along a direction of crystal growth.

### CROSS-REFERENCE TO RELATED APPLICATIONS

This disclosure claims a priority to Chinese Patent Application No. 202111146606.2 filed on Sep. 28, 2021, the disclosures of which are incorporated in their entirety by reference herein.

### TECHNICAL FIELD

The present disclosure relates to the field of semiconductor silicon wafer production, and in particular to a crystal puller for pulling monocrystalline silicon ingots.

### BACKGROUND

Silicon wafers used for producing of semiconductor electronic components such as integrated circuits are mainly produced by slicing monocrystalline silicon ingots pulled by the Czochralski method. The Czochralski method includes melting polysilicon in a quartz crucible to acquire a silicon melt, immersing a monocrystalline seed into the silicon melt, and continuously pulling the seed to move away from the surface of the silicon melt, thereby a monocrystalline silicon ingot is grown at the phase interface during pulling.

In the production process described above, it is advantageous to provide such a silicon wafer that has a Denuded Zone (DZ) extending into the body from the front surface and a Bulk Micro Defect (BMD) zone adjacent to the DZ and further extending into the body. The front surface refers to a surface of the silicon wafer on which electronic components are to be formed. The above-mentioned DZ is important, the reasons are as follows: in order to form electronic components on a silicon wafer, it is required that there is no crystal defects in the formation area of electronic components, otherwise it will lead to circuit breakage and other faults. Thus, the electronic components can be formed in the DZ to avoid the influence of crystal defects. The effect of the above-mentioned BMD is that it can produce an Intrinsic Getter (IG) effect on metal impurities to keep metal impurities in silicon wafers away from the DZ. Thus, the adverse effects such as the increase of leakage current and the reduction of gate oxide film quality caused by metal impurities can be avoided.

In the process of producing the above-mentioned silicon wafers with BMD zones, it is advantageous to dope silicon wafers with nitrogen. For example, in the case of a silicon wafer doped with nitrogen, it is possible to promote the formation of BMD with nitrogen as the core, so that the BMD can reach a certain density and effectively play a role as a source for absorbing metal impurities. Moreover, it is also have a beneficial effect on the density distribution of the BMD, such as making the density of the BMD more uniformly distributed in the radial direction of the silicon wafer, for another example, making the density of the BMD higher in the region adjacent to the DZ and gradually decreasing toward the inside of silicon wafer, etc.

In addition, during the silicon wafer production process, the BMD density of nitrogen-doped silicon wafers can be further increased by subjecting the nitrogen-doped silicon wafers to a heat treatment, because if such silicon wafers are subjected to the heat treatment, the supersaturated oxygen in the silicon wafer will precipitate out as oxygen precipitates, and such oxygen precipitates are also known as BMD. However, in the prior art, the heat treatment of silicon wafers needs to be performed in a heat treatment furnace being separated from the crystal puller. The existing heat treatment furnaces can be broadly classified into horizontal and vertical types according to the structure of the furnace inside. Both horizontal and longitudinal heat treatment furnaces can perform heat treatment upon only hundreds of silicon wafers at one time due to structural limitations, which is low efficient. Moreover, when the heat treatments are performed upon a batch of wafers, cross contamination may easily occur, which means impurities on some wafers may affect other wafers. In addition, since wafers are usually placed in a wafer boat in the heat treatment furnace and preformed heat treatment, slip dislocations of crystal lattices caused by thermal stress may be induced in the part of the wafer that is in contact with the wafer boat.

### SUMMARY

In order to solve the above-mentioned technical problems, embodiments of the present disclosure provide a crystal puller for pulling a monocrystalline silicon ingot, which solves the problem of low efficiency of heat treatment of silicon wafer, avoids the problem of cross contamination and the problem of slip dislocations of crystal lattices that may be caused by contacting between a wafer and a wafer boat during heat treatment of a silicon wafer.

The technical solutions of the present disclosure are as follow.

Embodiments of the present disclosure provide a crystal puller for pulling monocrystalline silicon ingots, the crystal puller comprises a heater configured with a heat treatment chamber, in which the heater is arranged in the crystal puller such that the monocrystalline silicon ingots are accessible to the heat treatment chamber by moving along a direction of crystal growth.

The embodiments of the present disclosure provide a crystal puller for pulling a monocrystalline silicon ingot which further includes a heater configured with a heat treatment chamber, which differs from the conventional crystal pullers. Therefore, unlike a way in which heat treatment is performed on the silicon wafers using a conventional technology, by using the crystal puller according to the present disclosure, the monocrystalline silicon ingot is pulled from melt, and then is heat treated in the crystal puller. Since the heat treatment chamber is arranged inside the crystal puller, there is unnecessary to transfer the monocrystalline silicon ingots into a conventional furnace. Moreover, the heat treatment may be performed on the entire monocrystalline silicon ingot in the crystal puller, thus greatly improving the efficiency of the heat treatment. In addition, since the heat treatment is performed on the monocrystalline silicon ingots instead of the silicon wafers, cross contamination and possible slip dislocations of crystal lattice caused by the contact between wafers and wafer boats are avoided during heat treatment of the wafers.

### BRIEF DESCRIPTION OF THE DRAWINGS

FIG. 1 is a schematic view of an embodiment of conventional crystal puller;

FIG. 2 is a schematic view of the crystal puller according to an embodiment of the present disclosure;

FIG. 3 is a schematic view of the crystal puller according to another embodiment of the present disclosure;

FIG. 4 is another schematic view of the crystal puller of FIG. 3;

FIG. 5 is a schematic view of the crystal puller according to still another embodiment of the present disclosure;

FIG. 6 is a schematic view of the crystal puller according to still another embodiment of the present disclosure.

### DETAILED DESCRIPTION

The technical solutions in the embodiments of the present disclosure will be described hereinafter in conjunction with the drawings in the embodiments of the present disclosure in a clear and complete manner.

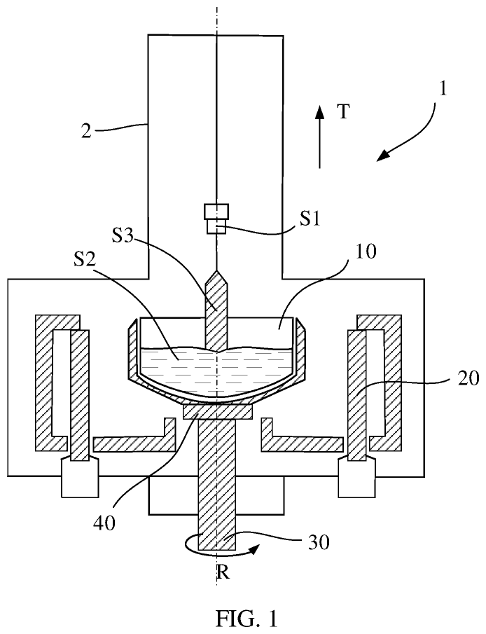

Refer to FIG. 1, FIG. 1 shows an embodiment of conventional crystal puller. As shown in FIG. 1, the crystal puller 1 comprising: a puller chamber enclosed by a housing 2, a crucible 10, a graphite heater 20, a crucible rotation mechanism 30 and a crucible supporter 40 arranged inside the puller chamber. The crucible 10 is supported by the crucible supporter 40 and the crucible rotation mechanism 30 is located below the crucible supporter 40 for driving the crucible 10 rotating around its own axis and in the direction R.

When the monocrystalline silicon ingots are pulled using the crystal puller 1, the process includes the following steps. First of all, placing the high purity polysilicon raw material into the crucible 10, and the crucible 10 is continuously heated by the graphite heater 20 while the crucible rotation mechanism 30 drives the crucible 10 rotating, to melt the polysilicon raw material contained in the crucible 10 into a molten state, i.e., melting into molten liquid S2. The heating temperature is maintained at about more than one thousand degrees Celsius. The gas filled in the puller is usually an inert gas that allows the polysilicon to melt and without generating unwanted chemical reactions. When the liquid surface temperature of the molten liquid S2 is controlled at the critical point of crystallization by controlling the hot zone provided by the graphite heater 20, by pulling the monocrystalline seed S1 located on the liquid surface upward along the direction T, the molten liquid S2 grows into the monocrystalline silicon ingot S3 in the crystal direction of the monocrystalline seed S1 as the mono-crystalline seed S1 is lifted upward. In order to finally produce silicon wafers with high BMD density, it may be optionally doped with nitrogen in raw material during the pulling process of monocrystalline silicon ingots, for example by filling the puller chamber of the crystal puller 1 with nitrogen gas during the pulling process, or by doping the silicon melt in the crucible 10 with nitrogen, so that the pulled monocrystalline silicon ingots and the silicon wafers slicing from the monocrystalline silicon ingots will be doped with nitrogen.

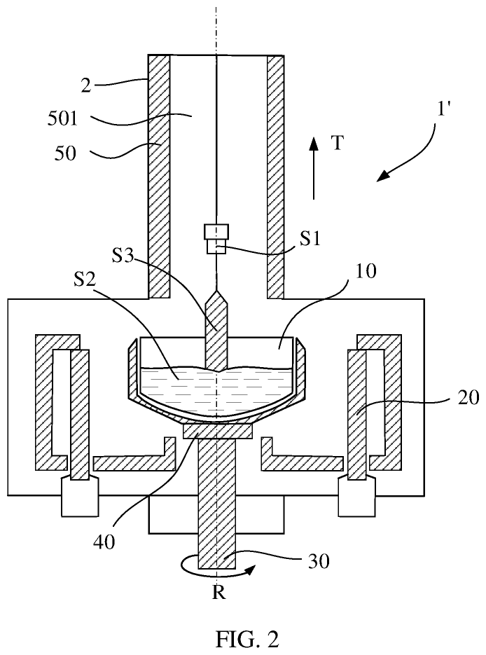

In order to further increase the BMD density within the monocrystalline silicon ingots, the embodiments of the present disclosure proposes a crystal puller with a heat treatment chamber, in which the monocrystalline silicon ingots are pulled from melt and heat treated in the crystal puller subsequently. Specifically, referring to FIG. 2, an embodiment of the present disclosure provides a crystal puller 1′ for pulling monocrystalline silicon ingots S3, and the crystal puller comprises a heater 50 configured with a heat treatment chamber 501. The heater 50 is arranged in the crystal puller such that the monocrystalline silicon ingots S3 are accessible to the heat treatment chamber 501 by moving along the direction of crystal growth T.

In the embodiment illustrated in FIG. 2, the shell 2 of the crystal puller 1′ is formed in a substantially cylindrical shape at the portion above the crucible 10, and the heater 50 is arranged against the inner peripheral wall of the cylindrical shape portion and configured with the heat treatment chamber 501. The heat treatment chamber 501 is also substantially cylindrical shape and has an opening towards the crucible 10 below. The diameter of the heat treatment chamber 501 is larger than the diameter of the monocrystalline silicon ingot S3, allowing the monocrystalline silicon ingot S3 pulled from the crucible 10 to continue moving along the direction of crystal growth T into the heat treatment chamber 501.

The monocrystalline silicon ingot S3 is heat-treated in heat treatment chamber 501 through the heater 50, whereby the supersaturated oxygen in the monocrystalline silicon ingot S3 precipitates as oxygen precipitates, i.e. precipitates BMD, to achieve the BMD density in monocrystalline silicon ingots S to the required level. It is unnecessary to slice the monocrystalline silicon ingots into silicon wafers and then transfer them in a separate heat treatment furnace for performing heat treatment. Thus the efficiency of heat treatment is improved and cross contamination problems and possible slip dislocations of crystal lattice caused by contact with the crystal boat due to the heat treatment in the silicon wafer form can be avoided.

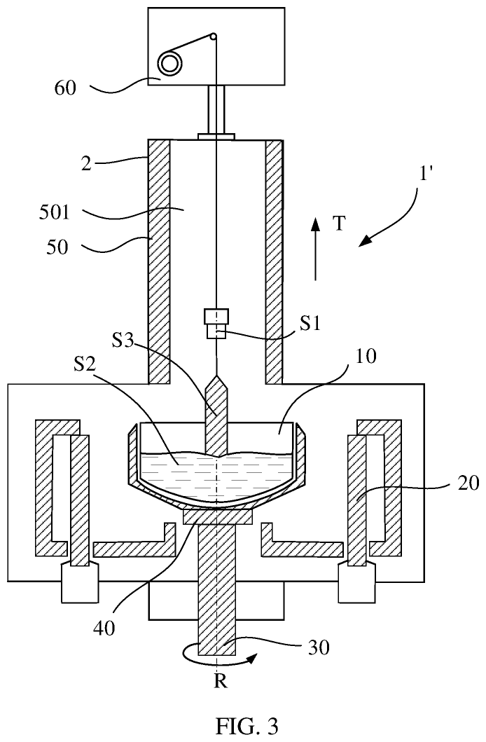

In order to achieve movement of the monocrystalline silicon ingot S3 along the direction of crystal growth T, refers to FIG. 3, it shows that the monocrystalline silicon ingot S3 is pulled from the molten liquid, and the crystal puller 1′ further comprising a pulling mechanism 60. The pulling mechanism 60 is configured to move the monocrystalline silicon ingot S3 along the direction of crystal growth T, in order to allow the monocrystalline silicon ingot S3 to grow from the phases interface and enter the heat treatment chamber 501.

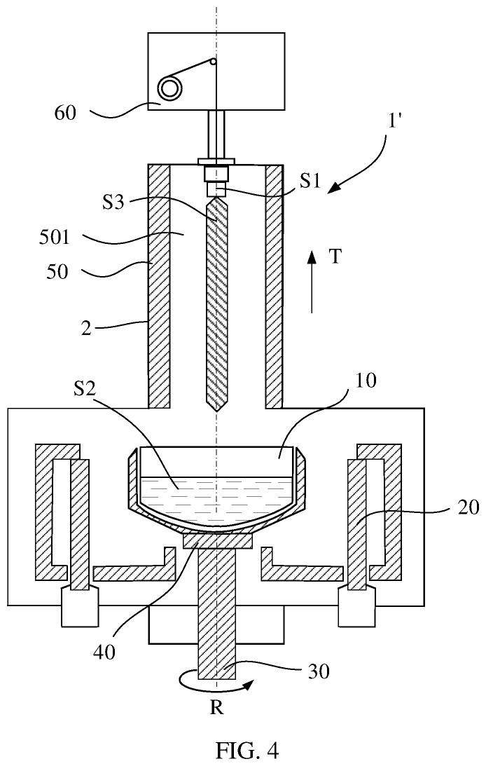

In order to make the monocrystalline silicon ingot S3 being heat treated under the predetermined conditions, optionally, the pulling mechanism 60 is configured to allow the entire monocrystalline silicon ingot S3 to stay in the heat treatment chamber 501 for a period of time as the heat treatment is required. As shown in FIG. 4, it is shown that the monocrystalline silicon ingot has been completely pulled from the molten liquid S2 and is in the heat treatment chamber 501, and the monocrystalline silicon ingot S3 has been lifted by the crystal pulling mechanism 60 to completely located in the heat treatment chamber 501, and the crystal pulling mechanism 60 can keep the monocrystalline silicon ingot S3 in that position until a predetermined heat treatment time has been experienced.

Since the monocrystalline silicon ingot S3 enters the heat treatment chamber 501 along the direction of crystal growth, the different parts of the monocrystalline silicon ingot S3 in the length direction actually enter the heat treatment chamber 501 at different time points. In order to ensure each part of the monocrystalline silicon ingot S3 to experience heat treatment under the same conditions, the time that individual part of the monocrystalline silicon ingot S3 stays in the heat treatment chamber 501 should be the heat treatment time as required.

In this regard, in the preferred embodiments of the present disclosure, the crystal pulling mechanism 60 is configured to move the monocrystalline silicon ingot S3 through the heat treatment chamber 501 at a constant speed, such that any cross section of the monocrystalline silicon ingot S3 stays in the heat treatment chamber 501 for a period of time as the heat treatment is required. As a result, the actual stay time of each part of the monocrystalline silicon ingot S3 in the heat treatment chamber 501 is the same, ensuring that the monocrystalline silicon ingot S3 is heat treated overall uniformly.

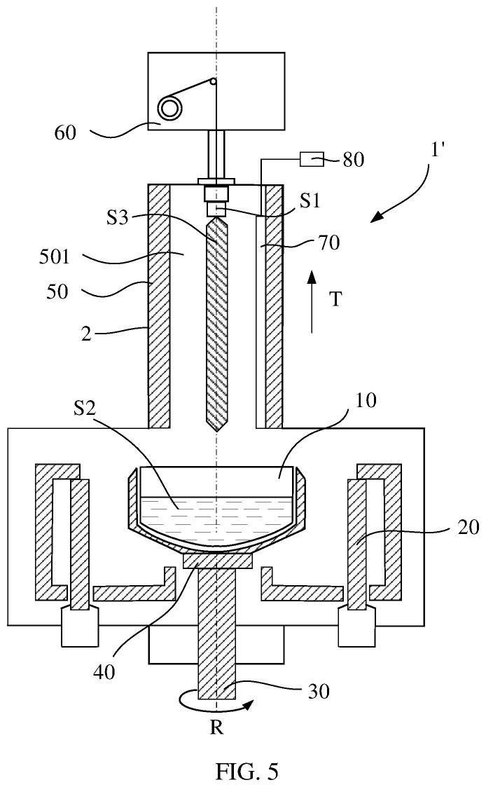

In the heat treatment process, in addition to the need to control the heat treatment time, the control of the heating temperature is also important. In the preferred embodiment of the present disclosure, refer to FIG. 5, the crystal puller further comprises a temperature sensor 70 arranged in the heat treatment chamber 501 for detecting the temperature of the monocrystalline silicon ingot S3 and a controller 80 connected to the temperature sensor 70. The controller 80 is configured to control the heating temperature of the heater 50 in accordance with the temperature detected by the temperature sensor 70 to provide the required heat treatment temperature.

As shown in FIG. 5, as an example, the temperature sensor 70 is arranged on the heater 50 and is closer to the monocrystalline silicon ingot S3, whereby the heater 50 is not always heated at a set constant temperature, but can provide an appropriate heat treatment temperature in accordance with the actual temperature of the monocrystalline silicon ingot S3. The arrangement of the temperature sensor 70 and the controller 80 can enable the heat treatment process to be performed in a more precise manner.

In order to further precisely control the heat treatment temperature provided by the heater 50, in the preferred embodiments of the present disclosure, the heater 50 may be controlled by the controller 80 such that different portions of the heater 50 along the direction of crystal growth T provide different temperatures simultaneously. As a result, if the actual temperatures of different portions of the mono-crystalline silicon ingot S3 along the direction of crystal growth T are different during the heat treatment process, the various portions of the heater 50 are able to provide heating temperatures based on these actual temperatures so that the actual experienced heat treatment temperatures of each part of the monocrystalline silicon ingot S3 are the same.

In the preferred embodiments of the present disclosure, the heat treatment temperature of the monocrystalline silicon ingot may be about 800 degrees Celsius.

In the preferred embodiments of the present disclosure, the heat treatment time may be about 2 hours.

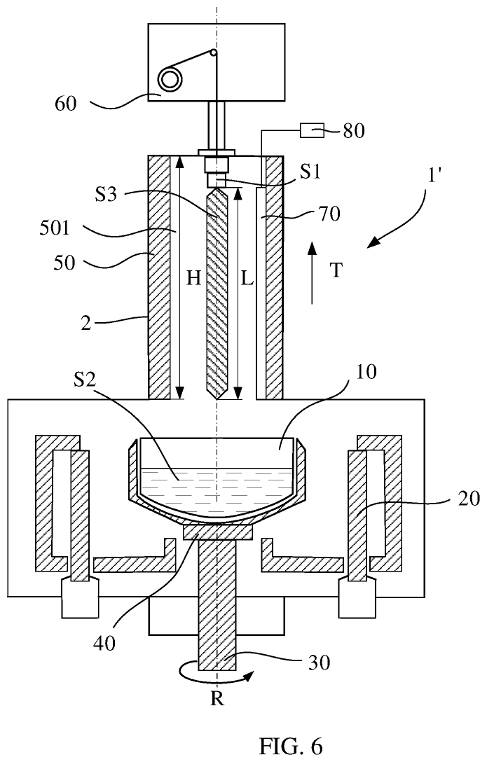

In one embodiment of the present disclosure, the crystal puller 1′ is arranged to enable the entire mono-crystalline silicon ingot S3 to undergo the heat treatment simultaneously in the heat treatment chamber 501. Preferably, as shown in FIG. 6, the length H of the heat treatment chamber 501 along the direction of crystal growth T is greater than or equal to the length L of the mono-crystalline silicon ingot S3, and thus the monocrystalline silicon ingot S3 can be completely located in the heat treatment chamber 501.

By using the crystal puller according to embodiments of the present disclosure, the BMD density within the mono-crystalline silicon ingot S3 is further increased. Preferably, the monocrystalline silicon ingot S3 has a BMD density of not less than 1E8ea/cm³ (1E8/cm³) after being performed heat treatment in the heat treatment chamber 501.

It should be noted that the technical solutions described in the embodiment of the present disclosure may be combined in any way without conflict.

The above description is merely the specific embodiment of the present disclosure, but the scope of the present disclosure is not limited thereto. Moreover, any person skilled in the art would readily conceive of modifications or substitutions within the technical scope of the present disclosure, and these modifications or substitutions shall also fall within the protection scope of the present disclosure. Therefore, the protection scope of the present disclosure should be determined by the scope of the attached claims.

1. A crystal puller for pulling a monocrystalline silicon ingot, comprising a heater configured with a heat treatment chamber, wherein the heater is arranged in the crystal puller such that the monocrystalline silicon ingot is accessible to the heat treatment chamber by moving along a direction of crystal growth.

2. The crystal puller according to claim 1, wherein the crystal puller further comprises a pulling mechanism, wherein the pulling mechanism is configured to move the monocrystalline silicon ingot along the direction of the crystal growth, in order to allow the monocrystalline silicon ingot to grow from a phase interface and enter the heat treatment chamber.

3. The crystal puller according to claim 2, wherein the pulling mechanism is configured to allow an entire monocrystalline silicon ingot to stay in the heat treatment chamber for a period of time necessary for performing heat treatment.

4. The crystal puller according to claim 2, wherein the crystal pulling mechanism is configured to move the monocrystalline silicon ingot through the heat treatment chamber at a constant speed, such that any cross section of the monocrystalline silicon ingot stays in the heat treatment chamber for a period of time necessary for performing heat treatment.

5. The crystal puller according to claim 1, wherein the crystal puller further comprises:
a temperature sensor arranged in the heat treatment chamber for detecting a temperature of the monocrystalline silicon ingot; and
a controller connected to the temperature sensor, and
wherein the controller is configured to control a heating temperature of the heater in accordance with the temperature detected by the temperature sensor to provide a temperature necessary for performing heat treatment.

6. The crystal puller according to claim 5, wherein the heater is controlled by the controller such that different portions of the heater along the direction of crystal growth provide different temperatures simultaneously.

7. The crystal puller according to claim 1, wherein a temperature for performing heat treatment on the monocrystalline silicon ingot is approximately 800 degrees Celsius.

8. (canceled)

9. The crystal puller according to claim 1, wherein a length of the heat treatment chamber along the direction of crystal growth is greater than or equal to a length of the monocrystalline silicon ingot such that the monocrystalline silicon ingot is completely located in the heat treatment chamber.

10. The crystal puller according to claim 1, wherein the monocrystalline silicon ingot has a BMD density of not less than 1E8ea/cm³ after being subjected to heat treatment in the heat treatment chamber.

11. The crystal puller according to claim 6, wherein a temperature for performing heat treatment on the monocrystalline silicon ingot is approximately 800 degrees Celsius.

12. The crystal puller according to claim 5, wherein a temperature for performing heat treatment on the monocrystalline silicon ingot is approximately 800 degrees Celsius.

13. The crystal puller according to claim 4, wherein a temperature for performing heat treatment on the monocrystalline silicon ingot is approximately 800 degrees Celsius.

14. The crystal puller according to claim 3, wherein a temperature for performing heat treatment on the monocrystalline silicon ingot is approximately 800 degrees Celsius.

15. The crystal puller according to claim 2, wherein a temperature for performing heat treatment on the monocrystalline silicon ingot is approximately 800 degrees Celsius.

16. The crystal puller according to claim 6, wherein a length of the heat treatment chamber along the direction of crystal growth is greater than or equal to a length of the monocrystalline silicon ingot such that the monocrystalline silicon ingot is completely located in the heat treatment chamber.

17. The crystal puller according to claim 5, wherein a length of the heat treatment chamber along the direction of crystal growth is greater than or equal to a length of the monocrystalline silicon ingot such that the monocrystalline silicon ingot is completely located in the heat treatment chamber.

18. The crystal puller according to claim 4, wherein a length of the heat treatment chamber along the direction of crystal growth is greater than or equal to a length of the monocrystalline silicon ingot such that the monocrystalline silicon ingot is completely located in the heat treatment chamber.

19. The crystal puller according to claim 3, wherein a length of the heat treatment chamber along the direction of crystal growth is greater than or equal to a length of the monocrystalline silicon ingot such that the monocrystalline silicon ingot is completely located in the heat treatment chamber.

20. The crystal puller according to claim 2, wherein a length of the heat treatment chamber along the direction of crystal growth is greater than or equal to a length of the monocrystalline silicon ingot such that the monocrystalline silicon ingot is completely located in the heat treatment chamber.

21. The crystal puller according to claim 3, wherein a time for performing heat treatment on the monocrystalline silicon ingot is approximately 2 hours.
